(19) United States
(12) Patent Application Publication
(10) Pub. No.: US 2007/0026141 A1
(43) Pub. Date: Feb. 1, 2007

(54) APPARATUS AND METHOD FOR PRODUCING MAGNETIC RECORDING MEDIUM

(75) Inventors: Masao Nakayama, Tokyo (JP); Hiromichi Kanazawa, Tokyo (JP); Yoshihiko Tanabe, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TDK CORPORATION, Tokyo (JP)

(21) Appl. No.: 11/460,118

(22) Filed: Jul. 26, 2006

(30) Foreign Application Priority Data
Jul. 27, 2005 (JP) 2005-217269

(51) Int. Cl. B05D 5/12; C23C 16/00

(52) U.S. Cl. 427/127; 118/726; 118/718; 427/255.5

(57) ABSTRACT

The present invention provides an apparatus and a method for producing a magnetic recording medium, which are free from base film breakage, capable of running a base film stably during a vapor deposition preparation stage and a vapor deposition step, and excellent in production efficiency. The production apparatus comprises a supply roll 14 for delivering a non-magnetic substrate 1, a rotary cooling drum 20, a crucible 17 housing a vapor deposition material 18, a maximum incident angle regulating mask 21A for regulating a maximum incident angle of an evaporated vapor deposition material to the non-magnetic substrate, a minimum incident angle regulating mask 21B for regulating a minimum incident angle, a pair of edge portion regulating masks 21C and 21D for regulating deposition on both edges in a width direction of the non-magnetic substrate 1 surface, a shutter 23 capable of opening and closing an aperture among masks 21A, 21B, 21C, and 21D, and a winding roll 16, wherein the edge portion regulating masks 21C and 21D are provided in such a manner as to keep a distance d_{A} between ends on upstream side of the edge portion regulating masks and the cooling drum 20 larger than a distance d_{B} between ends on downstream side of the edge portion regulating masks and the cooling drum 20.

### BACKGROUND OF THE INVENTION

1. Field of the Invention

The present invention relates to an apparatus and a method for producing a magnetic recording medium of a magnetic metal thin film type and, more specifically, to the apparatus and the method for producing the magnetic recording medium, which are free from base film breakage during a vapor deposition preparation stage and a vapor deposition step, and capable of enabling stable running of the base film.

2. Disclosure of the Related Art

Along with developments in information society, high density recording of a magnetic recording medium has been strongly demanded, and a magnetic recording layer is being developed from a coating type to a so-called magnetic metal thin film type. Since the magnetic recording medium of the magnetic metal thin film type does not contain any binder in its magnetic layer, unlike the coating type magnetic recording medium, the magnetic recording medium of the magnetic metal thin film type is capable of achieving a greater saturation magnetization of the medium and suitable for high density recording.

The magnetic metal thin film is formed by directly depositing a magnetic metal of Co, a Co—Ni alloy, a Co—Cr alloy, Co—O, a Co—Ni-O alloy, or the like by means of vacuum deposition on a polymer film serving as a non-magnetic substrate (base film), such as a polyester film, a polyamide film, and a polyimide film.

In a vapor deposition step, a magnetic metal vapor deposition material housed in a crucible is heated and evaporated by irradiation with an electron beam, and then the evaporated vapor deposition material is deposited on a surface of the polymer film running along a peripheral surface of a rotary cooling drum. The vapor deposition is generally performed in a region of an aperture between a maximum incident angle regulating mask for regulating a maximum incident angle of the vapor deposition material to the polymer film and a minimum incident angle regulating mask for regulating a minimum incident angle. In some cases, the polymer film is deteriorated by radiant heat generated by heating the vapor deposition material and heat of vapor deposition particles to result in production defect such as breakage.

Particularly, since edges in a width direction of the polymer film, i.e. so-called edge portions, tend to be detached from a surface of the cooling drum even in the case of running the film along the cooling drum with a tension being applied in a polymer film longitudinal (running) direction, it is difficult to achieve a sufficient cooling effect and the heat deterioration tends to occur on the edge portions. Also, if the vapor deposition particles adhered to the cooling drum are deposited on the cooling drum, it is difficult to transmit the coolness of the cooling drum to the film when the polymer film overlaps on the deposited vapor deposition particles, and such overlapping is one of the causes of the heat deterioration. Accordingly, a method of not forming a vapor deposition film on the edge portions by inhibiting adherence of vapor deposition particles with the use of a mask covering the edge portions of the polymer film has been employed. For example, the technology of restricting a vapor deposition range in the edge portions is disclosed in Japanese Laid-open Patent Publication No. Hei 11-200011 (1999).

However, according to Japanese Laid-open Patent Publication No. 2005-78732, in the case of using a PEN film as the polymer film, since the PEN film has the tendency to cause a so-called blocking phenomenon wherein the films are adhered to each other, the edge portions are overlapped with each other when the vapor deposition film is not formed on a portion of the edges of the base film, and the blocking occurs in the overlapped portion when the base film is wound in the form of a roll after the vapor deposition, thereby causing base film breakage.

In order to solve this problem, according to the publication, an edge portion mask for covering the edges in the width direction of the polymer base film is provided after adjusting a distance L between the cooling drum and the mask and an overlapping width w between the edges of the base film in the base film width direction and the mask to cause the vapor deposition particles to immigrate to the edges in the base film width direction, thereby forming a metal vapor deposition film having a predetermined film thickness smaller than that of the magnetic layer in the vicinity of the edge portion [0017].

Also, according to Japanese Laid-open Patent Publication No. 2005-787831, in the case where the polymer film is an aromatic polyamide (aramid, aromatic PA) film, since the aromatic PA film has the property of being electrically charged easily, only the edge portions are electrically charged due to the deposition of recoil electrons from an electron gun and secondary electrons, and the like when the vapor deposition film is not formed on a portion of the base film edge portion, thereby causing running defect (edge bending). The edge bending is the cause of wrinkle generation.

According to [0017] of the publication, the countermeasure taken in Japanese Laid-open Patent Publication No. 2005-78732 is taken in order to solve this problem.

Also, Japanese Laid-open Patent Publication No. 2000-285451 discloses a magnetic recording medium production method, wherein the magnetic film having a film thickness smaller than a predetermined film thickness is formed on the base film during a short time period immediately after the start of film forming, and then the magnetic film having the predetermined film thickness is formed on the base film after the short time period immediately after the start of film forming has passed. According to this publication, a thin film is formed on edges in the longitudinal direction of the film for the purpose of preventing the wrinkle generation at the start of the film formation in the vapor deposition step.

### SUMMARY OF THE INVENTION

In each of the conventional technologies, the countermeasures taken against the problems of the base film breakage and the wrinkle generation during the vapor deposition step and the running defect due to the base film breakage and the wrinkle generation have not been satisfactory.

The present inventors noted the base film breakage and the wrinkle generation during the vapor deposition preparation stage. Before the vapor deposition step for obtaining magnetic recording medium products, the vapor deposition preparation stage, i.e. a step for heat-melting vapor deposition material pellets housed in a crucible through irradiation with electron beam to melt the pellets into the state usable for the vapor deposition, is performed. The vapor deposition preparation stage is performed by slowly running the base film in a state where an aperture among a maximum incident angle regulating mask for regulating a maximum incident angle of the vapor deposition material to the base film, a minimum incident angle regulating mask for regulating a minimum incident angle, and a pair of edge portion regulating masks for regulating deposition on the edges in the width direction of the base film surface is closed by a shutter.

In view of influences of a sludge (unnecessary vapor deposition particle deposit) to be adhered around the masks during the vapor deposition, a gap is usually provided between the shutter and the masks. In the vapor deposition preparation stage, vapor deposition particles beginning to evaporate, recoil electrons from an electron gun, and secondary electrons are generated in addition to heat to influence on the running base film by immigrating through the gaps between the masks and the shutters. Due to influence of the heat, the base film is sometimes deteriorated. In order to mitigate the influence of heat, the base film is caused to run during the vapor deposition preparation stage. The vapor deposition particles cause the heat influence on the base film, but the vapor deposition particles adhered to the base film prevent the base film from being electrically charged easily. The recoil electrons and the secondary electrons adhered to the base film cause the base film to be easily electrically charged.

As described above, the base film is subject to the influences of heat during the vapor deposition preparation stage, and an electrical charge balance of the base film is varied depending on degrees of the adherences of the vapor deposition particles, the recoil electrons, and the secondary electrons. A change in the electrical charge balance of the base film can be a cause of the base film breakage and the wrinkle generation. When the change in the electrical charge balance is great, the base film breakage and the wrinkle generation can occur during the vapor deposition preparation stage to cause the running defect.

The present inventors have conducted extensive researches on suppression of the base film breakage and the wrinkle generation by reducing the change in base film electrical charge balance in the vapor deposition preparation stage. As a result, they have found that it is possible to suppress the base film breakage and the wrinkle generation in the vapor deposition preparation stage and the vapor deposition step performed subsequently to the vapor deposition preparation stage and it is possible to ensure a stable running of the base film by keeping a distance d_{A} between an end on upstream side of an edge portion regulating mask contacting a maximum incident angle regulating mask and a cooling drum larger than a distance d_{B} between an end on downstream side of the edge portion regulating mask contacting a minimum incident angle regulating mask and the cooling drum.

An object of the present invention is to provide a magnetic recording medium production apparatus which is free from base film breakage, capable of running a base film stably during a vapor deposition preparation stage and a vapor deposition step, and excellent in production efficiency. Another object of the present invention is to provide a magnetic recording medium production method which is free from base film breakage, capable of running a base film stably during a vapor deposition preparation stage and a vapor deposition step, and excellent in production efficiency.

The present invention comprises the followings:

(1) An apparatus for producing a magnetic recording medium which comprises:

in a vacuum chamber;

a supply roll for delivering a non-magnetic substrate;

a rotary cooling drum for running the non-magnetic substrate delivered from the supply roll along a peripheral surface of the drum;

a crucible housing a vapor deposition material and fixed in such a manner as to deposit the vapor deposition material evaporated by irradiation with an electron beam on a surface of the non-magnetic substrate running along the peripheral surface of the rotary cooling drum;

a maximum incident angle regulating mask for regulating a maximum incident angle of the evaporated vapor deposition material to the non-magnetic substrate, said mask being provided at an upstream side to cover an overall width of the non-magnetic substrate;

a minimum incident angle regulating mask for regulating a minimum incident angle of the vapor deposition material to the non-magnetic substrate, said mask being provided at a downstream side to cover the overall width of the non-magnetic substrate;

a pair of edge portion regulating masks for regulating deposition on both edges in a width direction of the non-magnetic substrate surface in a region between the maximum incident angle regulating mask and the minimum incident angle regulating mask;

a shutter capable of opening and closing an aperture among the maximum incident angle regulating mask and the minimum incident angle regulating mask and the pair of edge portion regulating masks; and

a winding roll for winding the non-magnetic substrate on whose surface a metal thin film magnetic layer is formed by the vapor deposition, wherein
the pair of edge portion regulating masks are provided in such a manner as to keep a distance d_{A} larger than a distance d_{B},

said distance d_{A} being a distance between ends on upstream side of the edge portion regulating masks contacting the maximum incident angle regulating mask and the cooling drum,

said distance d_{B} being a distance between ends on downstream side of the edge portion regulating masks contacting the minimum incident angle regulating mask and the cooling drum.

(2) A method for producing a magnetic recording medium which comprises:

in a vacuum chamber;

forming a metal thin film magnetic layer on a surface of a non-magnetic substrate by delivering the non-magnetic substrate from a supply roll to cause the delivered non-magnetic substrate to run along a peripheral surface of a rotary cooling drum and evaporating a vapor deposition material housed in a crucible by irradiation with an electron beam to deposit the vapor deposition material on the surface of the running non-magnetic substrate; and then

winding the non-magnetic substrate on which the metal thin film magnetic layer is formed onto a winding roll, wherein

the vapor deposition is performed in a region between a maximum incident angle regulating mask and a minimum incident angle regulating mask,

said maximum incident angle regulating mask being for regulating a maximum incident angle of the evaporated vapor deposition material to the non-magnetic substrate and provided at an upstream side to cover an overall width of the non-magnetic substrate,

said minimum incident angle regulating mask being for regulating a minimum incident angle of the vapor deposition material to the non-magnetic substrate and provided at a downstream side to cover the overall width of the non-magnetic substrate,

by providing a pair of edge portion regulating masks for regulating the vapor deposition on both edges in a width direction of the non-magnetic substrate surface in such a manner as to keep a distance d_{A} larger than a distance d_{B},

said distance d_{A} being a distance between ends on upstream side of the edge portion regulating masks contacting the maximum incident angle regulating mask and the cooling drum,

said distance d_{B} being a distance between ends on downstream side of the edge portion regulating masks contacting the minimum incident angle regulating mask and the cooling drum.

(3) The method for producing a magnetic recording medium according to (2), wherein the method further comprises a vapor deposition preparation stage,

in the vapor deposition preparation stage, the non-magnetic substrate is caused to run along the peripheral surface of the cooling drum in a state where an aperture among the maximum incident angel regulating mask and the minimum incident angle regulating mask and the pair of edge portion regulating masks is closed by a shutter while heat-melting the vapor deposition material housed in the crucible by the irradiation with the electron beam to change the vapor deposition material into a state usable for the vapor deposition, and then

the vapor deposition is performed in a state where the shutter is opened.

In the present invention, by keeping the distance d_{A} between the ends on upstream side of the edge portion regulating masks contacting the maximum incident angle regulating mask and the cooling drum larger than the distance d_{B} between the ends on downstream side of the edge portion regulating masks contacting the minimum incident angle regulating mask and the cooling drum, it is possible to facilitate the immigration of the vapor deposition particles to the vicinity of the vapor deposition start point at an upstream side, and the deposition of the vapor deposition particles to the edge portions of the non-magnetic substrate (base film). Therefore, the vapor deposition particles adhere to the edge portions at a favorable degree to make electrical charge states of the edge portions and other portions closer to each other. As a result, an electrical charge balance of the base film is improved to suppress the base film breakage and the wrinkle generation.

According to the present invention, an apparatus for producing a magnetic recording medium which is free from base film breakage, capable of running a base film stably during a vapor deposition preparation stage and a vapor deposition step, and excellent in production efficiency is provided. Also, according to the present invention, a method for producing a magnetic recording medium which is free from base film breakage, capable of running a base film stably during a vapor deposition preparation stage and a vapor deposition step, and excellent in production efficiency is provided.

### BRIEF DESCRIPTION OF THE DRAWINGS

FIG. 1 is a schematic block diagram showing one example of a production apparatus of the present invention.

FIG. 2 is a perspective view showing masks as viewed from a cooling drum of the production apparatus.

FIG. 3 is a diagram showing a position relationship between edge portion regulating masks and a base film surface in the production apparatus.

### DETAILED DESCRIPTION OF THE INVENTION

The apparatus and method for producing the magnetic recording medium of the present invention will be described with reference to the drawings. In this specification, upstream and downstream is based on a running direction of a base film 1.

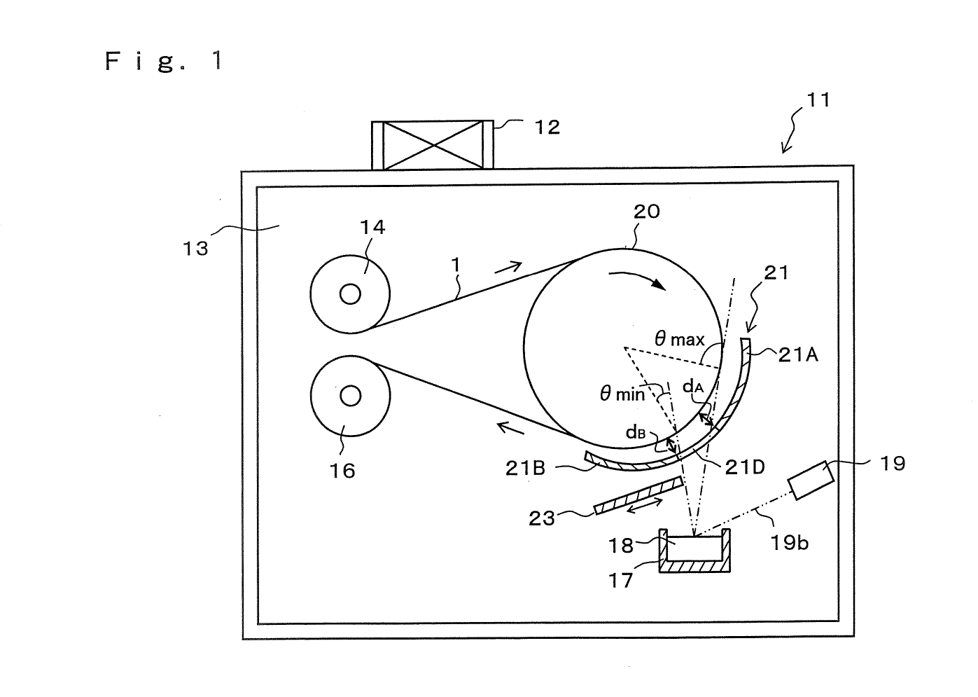

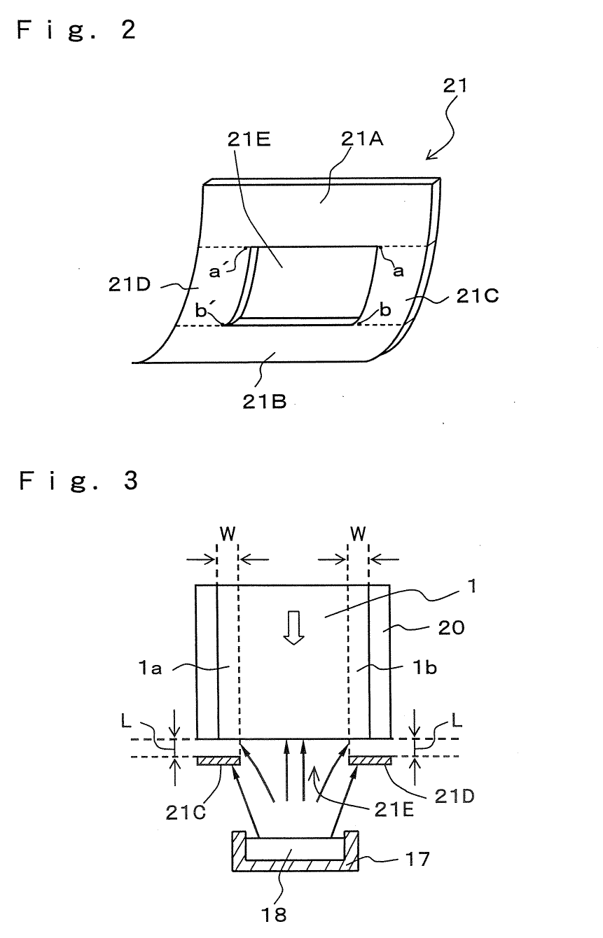

FIG. 1 is a schematic block diagram showing one example of the production apparatus of the present invention. FIG. 2 is a perspective view showing masks as viewed from a cooling drum of the production apparatus. FIG. 3 is a diagram showing a position relationship between edge portion regulating masks and a base film surface.

Referring to FIG. 1, the production apparatus 11 of the present invention comprises, in a vacuum chamber 13 inside which a predetermined pressure is maintained by a vacuum pump 12, a base film supply roll 14, a rotary cooling drum 20 for running the base film 1 delivered from the supply roll 14 along the peripheral surface of the rotary cooling drum, a crucible 17 housing a vapor deposition material (ferromagnetic metal) 18 and fixed in such a manner as to obliquely depositing the ferromagnetic metal evaporated by irradiation with an electron beam 19b emitted from an electron gun 19 on a surface of the base film 1 running along the peripheral surface of the rotary cooling drum 20, a mask 21 for regulating the vapor deposition particles, a shutter 23 capable of closing and opening an aperture, and a winding roll 16 for winding up the base film 1 on whose surface the metal thin film magnetic layer is formed by the vapor deposition.

Referring to FIG. 2, the mask 21 is obtainable by integrally forming a maximum incident angle regulating mask 21A regulating a maximum incident angle θmax of the vapor deposition material to the base film 1 and provided on an upstream side to cover an overall width of the base film 1, a minimum incident angle regulating mask 21B regulating a minimum incident angle θmin of the vapor deposition material to the base film 1 and provided on a downstream side from the maximum incident angle regulating mask 21A to cover the overall width of the base film 1, and a pair of edge portion regulating masks 21C and 21D regulating deposition on the both edges of the base film 1 in a width direction of the base film 1 in a region between the maximum incident angle regulating mask 21A and the minimum incident angle regulating mask 21B in a base film running direction, the mask 21 having a vertical section substantially having the form of an arc. A central portion defined by the masks 21A, 21B, 21C, and 21D serves as the aperture 21E for passing through the vapor deposition particles. Also, though not shown, masks for covering ends of lateral surfaces of the cooling drum 20 and continued from the edge portion regulating masks 21C and 21D may be provided.

The pair of the edge portion regulating masks 21C and 21D are provided in such a manner as to keep a distance d_{A} between ends a and a′ on upstream side of the edge portion regulating masks 21C and 21D contacting the maximum incident angle regulating mask 21A and the cooling drum 20 larger than a distance d_{B} between ends b and b′ on downstream side of the edge portion regulating masks 21C and 21D contacting the minimum incident angle regulating mask 21B and the cooling drum 20.

In the vicinity of a vapor deposition start point at the upstream side, the number of immigrating vapor deposition particles is smaller than that in a vapor deposition termination point at the downstream side. By keeping the relationship of distance d_{A}>distance d_{B}, immigration of the vapor deposition particles in the vicinity of the vapor deposition start point at the upstream side is facilitated to thereby facilitate deposition of the vapor deposition particles on the edge portions of the base film 1 in the vicinity of the vapor deposition start point. Therefore, a favorable degree of deposition of the vapor deposition particles on the edge portions are achieved to bring electrical charge states of the edge portions and other portions closer to each other.

The distance d_{A} between the ends a and a′ on upstream side of the edge portion regulating masks 21C and 21D and the cooling drum 20 and the distance d_{B} between the ends b and b′ on downstream side of the edge portion regulating masks 21C and 21D and the cooling drum 20 may appropriately be set so as to satisfy the relationship of distance d_{A}>distance d_{B} in the production apparatus. For example, the distance d_{B} may appropriately be 2 mm or less, preferably be from not less than 0.5 mm to not more than 2 mm, while the distance d_{A} may appropriately be larger than the distance d_{B} and 4 mm or less, preferably larger than 2 mm and equal to or less than 4 mm.

Since the vicinity of the ends a and a′ on upstream side of the edge portion regulating masks 21C and 21D is remote from the crucible 17, heat of the vapor deposition particles immigrating to the vicinity is relatively weak. Therefore, the heat deterioration of the running base film 1 due to the vapor deposition particles hardly occurs in the vicinity. By setting the distance d_{A} in the upstream ends a and a′ larger than the distance d_{B} in the downstream ends b and b′, e.g. by keeping the distance d_{A} larger than 2 mm and equal to or smaller than 4 mm, it is possible to achieve a favorable amount of the vapor deposition on the edge portions, which does not cause the heat deterioration. When the distance d_{A} exceeds 4 mm, the vapor deposition particle amount can be increased to cause the heat deterioration. When the distance d_{A} is equal to or less than 2 mm, an immigration amount of the vapor deposition particles is reduced to cause imperfect vapor deposition on the base film edge portions, thereby failing to achieve a sufficient blocking prevention effect.

On the other hand, since the vicinity of the ends b and b′ on downstream side of the edge portion regulating masks 21C and 21D is close to the crucible 17, the heat of the vapor deposition particles immigrating to the vicinity is strong. Therefore, the heat deterioration of the running base film 1 due to the vapor deposition particles tends to occur in the vicinity. When the distance d_{B} exceeds 2 mm, the heat deterioration can be caused. When the distance d_{B} is less than 0.5 mm, a contact with the running base film 1 can be caused.

In addition to the example shown in FIG. 2, the edge portion regulating masks 21C and 21D may have a shape of projecting toward the cooling drum 20 in relation to the maximum incident angle regulating mask 21A and the minimum incident angle regulating mask 21B.

Shown in FIG. 3 is a schematic position relationship between the edge portion regulating masks 21C and 21D and the base film 1. Referring to FIG. 3, each of the edge portion regulating masks 21C and 21D is so formed as to achieve the overlap width w with the corresponding one of edges 1a and 1b in the width direction of a surface of the running base film 1 and disposed in such a manner as to keep a distance L between the edge portion regulating masks and the cooling drum 20. With a reduction in overlapping width w, the immigration of the vapor deposition particles is facilitated, and, also, the immigration of the vapor deposition particles is facilitated with an increased in distance L. Therefore, the deposition of vapor deposition particles is facilitated on the edges 1a and 1b in the width direction of the base film surface. The distance L is equal to the distance d_{A} at the ends a and a′ on upstream side of the edge portion regulating masks 21C and 21D, i.e. at a contact point with the maximum incident angle regulating mask 21A. At the ends b and b′ on downstream side of the edge portion regulating masks 21C and 21D, i.e. at a contact point with the minimum incident angle regulating mask 21B, the distance L is equal to the distance d_{B}.

The distance L is increased gradually from the distance d_{B} in the ends b and b′ on downstream side of the edge portion regulating masks 21C and 21D to the distance d_{A} in the ends a and a′ on upstream side of the edge portion regulating masks 21C and 21D so as to satisfy the relationship of distance d_{A}>distance d_{B} described in the foregoing. The overlapping width w may be set to 2 to 5 times of the distance d_{B}. That is, 2≦w/d_{B}≦5 holds. Though it depends on other conditions, when the overlapping width w is less than 2 times of the distance d_{B}, the immigration amount of the vapor deposition particles is increased too much to cause contamination of the cooling drum 20 and the heat deterioration of the base film edge portions. Also, when the overlapping width w exceeds 5 times of the distance d_{B}, the immigration amount of the vapor deposition particles is reduced to cause insufficient vapor deposition on the base film edge portions, thereby failing to achieve the sufficient blocking prevention effect.

The shutter 23 is capable of opening and closing the aperture 21E of the mask 21 and may be in the form of a plate as shown in the drawings or an ark so as to fit the mask 21A and the mask 21B.

A gas supply inlet (not shown) facing to the aperture 21E of the mask 21 is provided between the cooling drum 20 and the minimum incident angle regulating mask 21B or between the minimum incident angle regulating mask 21B and the shutter 23.

The metal thin film magnetic layer is formed by using the production apparatus 11 as described below.

To start with, the vapor deposition preparation stage is performed. The vacuum pump 12 is actuated to keep a predetermined pressure inside the vacuum chamber 13. In a state where the aperture 21E of the mask 21 is closed by the shutter 23, the base film 1 is delivered from the supply roll 14 to run along the peripheral surface of the cooling drum 20. A running speed in this stage is usually slower than a running speed in the subsequent vapor deposition step. The vapor deposition material pellets 18 housed in the crucible 17 are heat-melted by irradiation with the electron beam 19b to change the pellets into a state usable for the vapor deposition. The electron beam 19b is scanned in the width direction of the base film 1.

Next, the vapor deposition step is performed. The shutter 23 is moved to open the aperture 21E. The base film 1 is caused to run continuously with the running speed of the base film 1 being increased as compared to the running speed in the vapor deposition preparation stage. An oxidizing gas such as an oxygen gas is supplied from the gas supply inlet to the aperture 21E simultaneously with continuing the irradiation of the vapor deposition material 18 melted and housed in the crucible with the electron beam 19b to heat-evaporating the vapor deposition material, thereby generating the vapor deposition particles. The vapor deposition is generally performed on the surface of the base film 1 running in the region of the aperture 21E to form the metal thin film magnetic layer. The base film 1 after the metal thin film magnetic layer formation is wound around the winding roll 16. A tension during the winding may suitably be in the range of 4.8 kg to 12.9 kg per 1 meter.

In the present invention, the distance d_{A} is larger than the distance d_{B}. Therefore, the immigration of the vapor deposition particles to the vicinity of the vapor deposition start point at the upstream side is facilitated, so that the deposition of the vapor deposition particles on the edge portions of the base film 1 is facilitated. Accordingly, a favorable amount of the vapor deposition particles is deposited on the edge portions to make the electrical charge states of the edge portions and the portions other than the edge portions closer to each other. As a result, the electrical charge balance of the base film 1 is improved to suppress the base film breakage and the wrinkle generation. Such effect is of course achieved in the vapor deposition step and is particularly prominent in the vapor deposition preparation stage. By performing the vapor deposition preparation stage stably, it is possible to perform the subsequent vapor deposition step stably, thereby enabling efficient production of magnetic recording mediums.

### EXAMPLES

Hereinafter, the present invention will be described in more detail in conjunction with examples, but the present invention is not limited to the examples.

### Examples 1 to 3

### By Using the Production Apparatus Shown in FIGS. 1 to 3

A metal thin film magnetic layer was formed on a polyethylene-2,6-naphthalate (PEN) film 1 having a thickness of 4.7 μm by using the production apparatus 11 shown in FIGS. 1 to 3. Cobalt pellets were used as the vapor deposition material 18. A crucible made from magnesium oxide was used as the crucible 17. The overlapping width w of the edge portion regulating masks 21C and 21D with the edges 1a and 1b in the width direction of the surface of the base film 1 was set to 4 mm. The distance d_{A} between the ends a and a′ on upstream side of the edge portion regulating masks 21C and 21D and the cooling drum 20 and the distance d_{B} between the ends b and b′ on downstream side of the edge portion regulating masks 21C and 21D and the cooling drum 20 were set as described below.

Example 1: distance d_{A}=3 mm, distance d_{B}=1 mm

Example 2: distance d_{A}=3 mm, distance d_{B}=2 mm

Example 3: distance d_{A}=4 mm, distance d_{B}=2 mm

Vapor Deposition Preparation Stage

A pressure inside the vacuum chamber 13 was maintained to 10⁻³ Pa by using the vacuum pump 12. In a state where the aperture 21E of the mask 21 was closed by the shutter 23, the PEN film 1 was caused to run, and the cobalt pellets 18 housed in the crucible 17 were heat-melted by the irradiation of the cobalt pellets 18 with the electron beam 19b emitted from the electron gun 19.

Vapor Deposition Step

Next, when the pellets became usable for vapor deposition, the shutter 23 was moved to open the aperture 21E. A running speed of the base film 1 was increased from that in the vapor deposition preparation stage while continuously running the base film 1, and the oxygen gas was introduced from the gas supply inlet while continuing the irradiation of the vapor deposition material 18 housed in the crucible 17 with the electron beam 19b to perform vapor deposition, thereby forming a magnetic layer having a thickness of 170 nm.

In each of the examples, 10 base film rolls were subjected to the experiment, and the number of base film rolls in which the base film breakage occurred as well as the number of base film rolls in which wrinkle generation occurred during the vapor deposition preparation stage were checked. Likewise, the number of base film rolls in which the base film breakage occurred as well as the number of base film rolls in which a wrinkle generation occurred and the number of base film rolls in which heat deterioration occurred in base film edge portion, during the vapor deposition step, were checked. The results are shown in Table 1 wherein the numbers of the base film rolls checked as described above are used as the running defect generation frequency.

The base film breakage means a case wherein the base film was wound in adhered state around the cooling drum due to the electrical charge to be broken and to stop the production line.

The wrinkle generation means a case wherein a wrinkle except for a wrinkle due to the base film breakage or the heat deterioration was visually observed on the base film or the magnetic layer.

The heat deterioration means a case wherein a hole formed on the base film edge portions was visually observed.

### Comparative Examples 1 to 3

An experiment was conducted by using the apparatus shown in FIGS. 1 to 3 and 10 base film rolls for each of the comparative examples in the same manner as in Example 1 except for changing the distance d_{A} between the ends a and a′ on upstream side of the edge portion regulating masks 21C and 21D and the cooling drum 20 and the distance d_{B} between the ends b and b′ on downstream side of the edge potion regulating masks 21C and 21D and the cooling drum 20 as described below.

Comparative Example 1: distance d_{A}=1 mm, distance d_{B}=1 mm

Comparative Example 2: distance d_{A}=2 mm, distance d_{B}=2 mm

Comparative Example 3: distance d_{A}=3 mm, distance d_{B}=3 mm

As is apparent from Table 1, in Examples 1 to 3, the base film breakage and the wrinkle generation were not observed in the vapor deposition preparation stage and the vapor deposition step, and the heat deterioration was not observed in the vapor deposition step.

TABLE 1

| | Pro- | | | | | | |
|---|---|---|---|---|---|---|---|
| | duction | | Running defect generation frequency | | | | |
| | appa- | | Vapor deposition | | | | |
| | ratus | | preparation stage | | Vapor deposition step | | |
| | d_{A} | d_{B} | Base film | Wrinkle | Base film | Wrinkle | Heat |
| | (mm) | (mm) | breakage | generation | breakage | generation | deterioration |
| Example 1 | 3 | 1 | 0/10 | 0/10 | 0/10 | 0/10 | 0/10 |
| Example 2 | 3 | 2 | 0/10 | 0/10 | 0/10 | 0/10 | 0/10 |
| Example 3 | 4 | 2 | 0/10 | 0/10 | 0/10 | 0/10 | 0/10 |
| Comparative | 1 | 1 | 6/10 | 3/10 | 0/10 | 3/10 | 0/10 |
| Example 1 | | | | | | | |
| Comparative | 2 | 2 | 3/10 | 3/10 | 0/10 | 2/10 | 0/10 |
| Example 2 | | | | | | | |
| Comparative | 3 | 3 | 0/10 | 0/10 | 0/10 | 0/10 | 5/10 |
| Example 3 | | | | | | | |

What is claimed is:

1. An apparatus for producing a magnetic recording medium which comprises:
in a vacuum chamber;
a supply roll for delivering a non-magnetic substrate;
a rotary cooling drum for running the non-magnetic substrate delivered from the supply roll along a peripheral surface of the drum;
a crucible housing a vapor deposition material and fixed in such a manner as to deposit the vapor deposition material evaporated by irradiation with an electron beam on a surface of the non-magnetic substrate running along the peripheral surface of the rotary cooling drum;
a maximum incident angle regulating mask for regulating a maximum incident angle of the evaporated vapor deposition material to the non-magnetic substrate, said mask being provided at an upstream side to cover an overall width of the non-magnetic substrate;
a minimum incident angle regulating mask for regulating a minimum incident angle of the vapor deposition material to the non-magnetic substrate, said mask being provided at a downstream side to cover the overall width of the non-magnetic substrate;
a pair of edge portion regulating masks for regulating deposition on both edges in a width direction of the non-magnetic substrate surface in a region between the maximum incident angle regulating mask and the minimum incident angle regulating mask;
a shutter capable of opening and closing an aperture among the maximum incident angle regulating mask and the minimum incident angle regulating mask and the pair of edge portion regulating masks; and
a winding roll for winding the non-magnetic substrate on whose surface a metal thin film magnetic layer is formed by the vapor deposition, wherein
the pair of edge portion regulating masks are provided in such a manner as to keep a distance d_{A} larger than a distance d_{B},
said distance d_{A} being a distance between ends on upstream side of the edge portion regulating masks contacting the maximum incident angle regulating mask and the cooling drum,
said distance d_{B} being a distance between ends on downstream side of the edge portion regulating masks contacting the minimum incident angle regulating mask and the cooling drum.

2. A method for producing a magnetic recording medium which comprises:
in a vacuum chamber;
forming a metal thin film magnetic layer on a surface of a non-magnetic substrate by delivering the non-magnetic substrate from a supply roll to cause the delivered non-magnetic substrate to run along a peripheral surface of a rotary cooling drum and evaporating a vapor deposition material housed in a crucible by irradiation with an electron beam to deposit the vapor deposition material on the surface of the running non-magnetic substrate; and then
winding the non-magnetic substrate on which the metal thin film magnetic layer is formed onto a winding roll, wherein
the vapor deposition is performed in a region between a maximum incident angle regulating mask and a minimum incident angle regulating mask,
said maximum incident angle regulating mask being for regulating a maximum incident angle of the evaporated vapor deposition material to the non-magnetic substrate and provided at an upstream side to cover an overall width of the non-magnetic substrate,
said minimum incident angle regulating mask being for regulating a minimum incident angle of the vapor deposition material to the non-magnetic substrate and provided at a downstream side to cover the overall width of the non-magnetic substrate,
by providing a pair of edge portion regulating masks for regulating the vapor deposition on both edges in a width direction of the non-magnetic substrate surface in such a manner as to keep a distance d_{A} larger than a distance d_{B},
said distance d_{A} being a distance between ends on upstream side of the edge portion regulating masks contacting the maximum incident angle regulating mask and the cooling drum,
said distance d_{B} being a distance between ends on downstream side of the edge portion regulating masks contacting the minimum incident angle regulating mask and the cooling drum.

3. The method for producing a magnetic recording medium according to claim 2, wherein the method further comprises a vapor deposition preparation stage,
in the vapor deposition preparation stage, the non-magnetic substrate is caused to run along the peripheral surface of the cooling drum in a state where an aperture among the maximum incident angel regulating mask and the minimum incident angle regulating mask and the pair of edge portion regulating masks is closed by a shutter while heat-melting the vapor deposition material housed in the crucible by the irradiation with the electron beam to change the vapor deposition material into a state usable for the vapor deposition, and then
the vapor deposition is performed in a state where the shutter is opened.
